(19) United States
(12) Patent Application Publication
(10) Pub. No.: US 2007/0171710 A1
(43) Pub. Date: Jul. 26, 2007

(54) SEMICONDUCTOR STORAGE DEVICE AND METHOD OF USING SEMICONDUCTOR STORAGE DEVICE

(75) Inventors: Kumiko MITO, Osaka (JP); Takashi Oshikiri, Osaka (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MegaChips LSI Solutions Inc., Osaka-shi (JP)

(21) Appl. No.: 11/614,427

(22) Filed: Dec. 21, 2006

(30) Foreign Application Priority Data
Jan. 24, 2006 (JP) 2006-014985

(51) Int. Cl. G11C 16/04

(52) U.S. Cl. 365/185.03

(57) ABSTRACT

A memory cell array includes a memory cell transistor storing data of a value in accordance with a set threshold voltage. A writing control unit controls writing of data in the memory cell transistor. A memory cell driving unit writes data in the memory cell transistor under the control of the writing control unit. The writing control unit is capable of setting at least three types of threshold voltages having different values for the memory cell transistor by controlling the memory cell driving unit, and uses only a plurality types of threshold voltages having values not adjacent to each other of the at least three types of threshold voltages in writing data in the memory cell transistor.

### BACKGROUND OF THE INVENTION

1. Field of the Invention

The present invention relates to a semiconductor storage device storing data in a memory cell transistor, and a method of using the semiconductor storage device.

2. Description of the Background Art

Semiconductor storage devices called multi-level memories have been conventionally proposed, which are capable of storing data of three or more values per cell by setting three or more types of threshold voltages for one memory cell transistor. For example, Japanese Patent Application Laid-Open No. 11-339495 (1999) describes a technique of a flash memory capable of storing three bits of data, namely, data of eight values from “000” to “111”, per cell. Japanese Patent Application Laid-Open No. 11-154394 (1999) also discusses a technique of a multi-level memory.

Japanese Patent Application Laid-Open No. 2003-273256 describes a technique of a non-volatile memory that physically includes two regions for accumulating electric charge.

In such conventional semiconductor storage devices as mentioned above, data written in a memory cell transistor cannot always be read normally due to transitions of threshold voltages set for the memory transistor or current noise generated in a sense amplifier at the time of reading, sometimes resulting in an error in read data.

### SUMMARY OF THE INVENTION

An object of the present invention is to provide a technique capable of reducing the occurrence of data error in a semiconductor storage device including a memory cell transistor.

In an aspect of the present invention, a semiconductor storage device includes: a first memory cell transistor storing first data of values in accordance with first plurality types of threshold voltages; a writing control unit controlling writing of the first data in the first memory cell transistor; and a memory cell driving unit writing the first data in the first memory cell transistor under control of the writing control unit. The writing control unit is capable of setting at least three types of threshold voltages having different values for the first memory cell transistor by controlling the memory cell driving unit, and uses only threshold voltages having values not adjacent to each other of the at least three types of threshold voltages as the first plurality types of threshold voltages in writing the first data in the first memory cell transistor.

Of the settable threshold voltages for the memory cell transistor, only a plurality types of threshold voltages having values not adjacent to each other are used in writing data in the memory cell transistor. This allows the space to be increased between threshold voltages actually set for the memory cell transistor. Accordingly, the occurrence of error in read data from the memory cell transistor can be reduced, although the amount of information that can be stored in one memory cell transistor decreases.

In another aspect of the present invention, the writing control unit uses only a minimum threshold voltage and a maximum threshold voltage of the at least three types of threshold voltages as the first plurality types of threshold voltages in writing the first data in the first memory cell transistor by controlling the memory cell driving unit.

The use of only the minimum and maximum threshold voltages of the settable threshold voltages for the memory cell transistor allows the space to be further increased between threshold voltages set for the memory cell transistor. Accordingly, the occurrence of error in read data from the memory cell transistor can be reduced more reliably.

In another aspect of the present invention, the semiconductor storage device further includes a second memory cell transistor storing second data of values in accordance with second plurality types of threshold voltages. The writing control unit further controls writing of the second data in the second memory cell transistor. The memory cell driving unit further writes the second data in the second memory cell transistor under control of the writing control unit. The writing control unit uses all of the at least three types of threshold voltages as the second plurality types of threshold voltages in writing the second data in the second memory cell transistor by controlling the memory cell driving unit.

The different methods of setting threshold voltages for the memory cell transistors in writing data in the memory cell transistors attain the first memory cell transistors having a relatively low probability of occurrence of data error although the amount of information that can be stored in one memory cell is relatively small, and the second memory cell transistors having a relatively large amount of information that can be stored in one memory cell although the probability of occurrence of data error is relatively high. Thus, the first and second memory cell transistors can be formed using the same structure. Therefore, a semiconductor storage device having two types of memory cells can be realized using a simple structure, which cuts the manufacturing cost of the semiconductor storage device.

A still another aspect of the present invention is directed to a method of using a semiconductor storage device including a memory cell transistor, the memory cell transistor storing data of values in accordance with a plurality types of threshold voltages and being capable of being set with at least three types of threshold voltages having different values.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram illustrating the structure of an information processing device according to a first preferred embodiment of the present invention.

FIG. 2 is a block diagram illustrating the structure of a memory cell array according to the first preferred embodiment.

FIG. 3 illustrates distribution of threshold voltages of a memory cell transistor in a second memory region according to the first preferred embodiment.

FIG. 4 is a cross-sectional view illustrating the structure of a memory cell transistor according to a second preferred embodiment of the present invention.

FIG. 5 depicts a method of writing data in a first memory region according to the second preferred embodiment.

FIG. 6 depicts a method of reading data from the first memory region according to the second preferred embodiment.

FIG. 7 depicts a modification to the method of writing data in the first memory region according to the second preferred embodiment.

FIG. 8 depicts a modification to the method of reading data from the first memory region according to the second preferred embodiment.

FIG. 9 is a block diagram illustrating the structure of a modification to the information processing device according to the first and second preferred embodiments.

### DESCRIPTION OF THE PREFERRED EMBODIMENTS

### First Preferred Embodiment

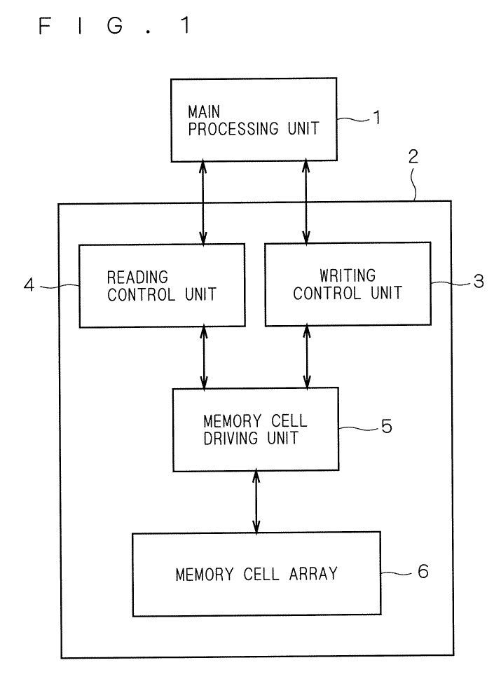

FIG. 1 is a block diagram illustrating the structure of an information processing device according to a first preferred embodiment of the present invention. The information processing device according to the first preferred embodiment is a communication device such as a cellular phone, or a display device such as a liquid crystal display device, for example. As shown in FIG. 1, the information processing device includes a main processing unit 1 that performs signal processing concerning principal functions of the information processing device, and a semiconductor storage device 2 that stores an operation program of the main processing unit 1 and various kinds of data from the main processing unit 1 and the like in a non-volatile manner. The semiconductor storage device 2 is a memory card, for example, and is removably connected to the main processing unit 1 via a connector.

When the information processing device according to this embodiment is a cellular phone in digital communication mode, the main processing unit 1 performs signal processing concerning communications with a base station or a terminal on the other end, such as decoding processing or coding processing. When the information processing device according to this embodiment is a liquid crystal display device, the main processing unit 1 performs signal processing concerning image display, such as image processing.

The semiconductor storage device 2 includes a writing control unit 3, a reading control unit 4, a memory cell driving unit 5, and a memory cell array 6. The writing control unit 3 controls writing of data in the memory cell array 6 serving as a memory unit. The reading control unit 4 controls reading of data from the memory cell array 6. The memory cell driving unit 5 includes an address decoder circuit, a word line driver, a bit line driver, a sense amplifier circuit, and the like. The memory cell driving unit 5 writes data in the memory cell array 6 under the control of the writing control unit 3, and reads data from the memory cell array 6 under the control of the reading control unit 4.

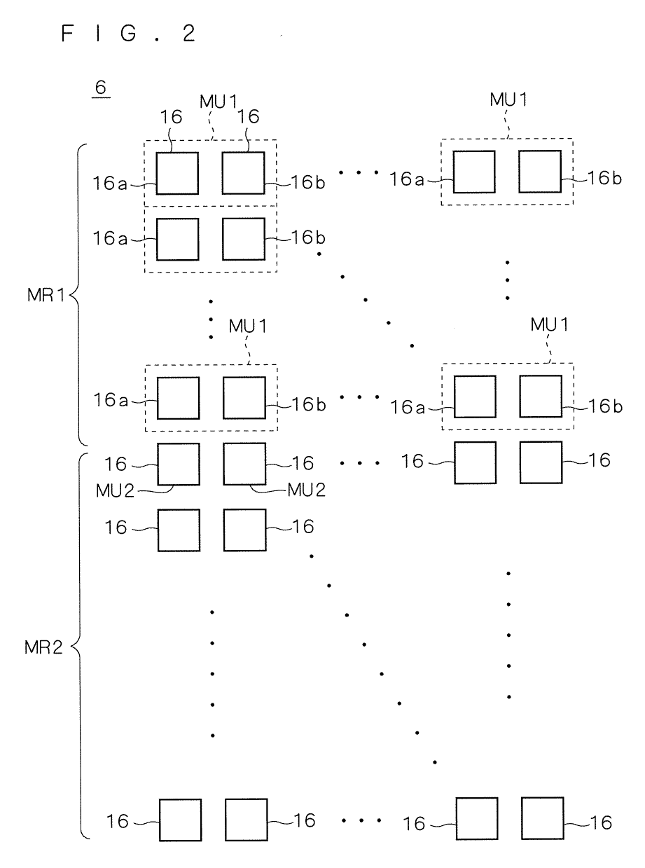

FIG. 2 is a block diagram illustrating the structure of the memory cell array 6. As shown, the memory cell array 6 includes a plurality of memory cell transistors 16 arranged in a matrix. The plurality of memory cell transistors 16 are divided into a first memory region MR1 and a second memory region MR2. In the first memory region MR1, a plurality of memory cell transistors 16 form a memory unit MU1, and data of M values (M≧3) can be stored in each memory unit MU1. In this embodiment, two memory cell transistors 16 form the memory unit MU1 by way of example, and two bits of data, namely, data of four values of “00”, “01”, “10” and “11” can be stored in each memory unit MU1. One of the two memory cell transistors 16 forming the memory unit MU1 may henceforth be called a “memory cell transistor 16a ”, and the other one may be called a “memory cell transistor 16b”.

In the second memory region MR2, on the other hand, one memory cell transistor 16 forms a memory unit MU2, and data of M values, e.g. data of four values of “00”, “01”, “10” and “11” can be stored in each memory unit MU2, namely, in each memory cell transistor 16.

The memory cell transistor 16 according to this embodiment is a memory cell transistor having a conductive floating gate, like the one employed in a flash memory. A threshold voltage of the memory cell transistor 16 can be changed by changing the amount of electrons injected into the floating gate. The memory cell transistor 16 stores data of a value in accordance with a set threshold voltage.

For the memory cell transistor 16 according to this embodiment, M types of threshold voltages Vth1 to VthM having different values can be set by the memory cell driving unit 5 under the control of the writing control unit 3. For example, four types of threshold voltages Vth1 to Vth4 (Vth1<Vth2<Vth3<Vth4) can be set for the memory cell transistor 16. Of the threshold voltages Vth1 to Vth4, only N (≧2) types of threshold voltages having values not adjacent to each other are used in writing data in the memory cell transistor 16 in the first memory region MR1, while all of the four types of threshold voltages Vth1 to Vth4 are used in writing data in the memory cell transistor 16 in the second memory region MR2.

In this embodiment, two types of the settable threshold voltages Vth1 to Vth4, i.e. the minimum threshold voltage Vth1 and the maximum threshold voltage Vth4 are used in writing data in the memory cell transistor 16 in the first memory region MR1. The two types of threshold voltages Vth1 and Vth4 are used to write one bit of data in the memory cell transistor 16 in the first memory region MR1. For example, the threshold voltage Vth1 is set for writing data of “0” in the memory cell transistor 16, and the threshold voltage Vth4 is set for writing data of “1”. The entire memory unit MU1 including the two memory cell transistors 16a and 16b thus stores two bits of data. For example, a value of a higher-order bit B1 of the two bits of data to be written in the memory unit MU1 is written in the memory cell transistor 16a, and a value of a lower-order bit B0 is written in the memory cell transistor 16b. When data is read from the memory unit MU1, one bit of data is read from each of the memory cell transistors 16a and 16b forming the memory unit MU1, to be combined and output as two bits of data. The threshold voltages Vth1 and Vth3, or the threshold voltages Vth2 and Vth4 may be used instead of the threshold voltages Vth1 and Vth4.

On the other hand, the threshold voltages Vth1 to Vth4 are used to write two bits of data in the memory cell transistor 16 in the second memory region MR2. For example, the threshold voltage Vth1 is set for writing data of “11” in the memory cell transistor 16, and the threshold voltage Vth2 is set for writing data of “01”. The threshold voltage Vth3 is set for writing data of “00” in the memory cell transistor 16, and the threshold voltage Vth4 is set for writing data of “10”.

FIG. 3 illustrates distribution of the threshold voltages of the memory cell transistor 16 in the second memory region MR2. The horizontal axis of FIG. 3 indicates the threshold voltages of the memory cell transistor 16, and the vertical axis indicates the number of memory cell transistors 16 having the threshold voltages. As shown, when data of “11” is written in the memory cell transistor 16, the actual threshold voltage of the memory cell transistor 16 is not exactly Vth1 but forms a distribution mountain with the threshold voltage Vth1 as its center. Similar mountains are formed with respect to the threshold voltages Vth2 to Vth4 as well. In a multi-level memory, where the space between distribution mountains of adjacent threshold voltages is narrower than that in a two-value memory, a slight change in threshold voltage of the memory cell transistor 16 that belongs to a certain distribution mountain will cause the threshold voltage to easily enter another distribution mountain. A multi-level memory therefore carries a higher probability of occurrence of error in read data than a two-value memory.

Meanwhile, the space between set threshold voltages can be increased in the memory cell transistor 16 in the first memory region MR1 because, of the settable four types of threshold voltages Vth1 to Vth4, only the threshold voltages Vth1 and Vth4 having values not adjacent to each other are actually set. Thus, a slight change in threshold voltage of the memory cell transistor 16 that belongs to a certain distribution mountain does not cause the threshold voltage to enter another distribution mountain. The result is a low probability of occurrence of error in read data from the memory cell transistor 16, although the amount of information that can be stored in one memory cell transistor 16 decreases.

The methods of writing data in the first memory region MR1 and second memory region MR2, and the methods of reading data from the first memory region MR1 and second memory region MR2 will now be described in detail.

Upon receipt of two bits of to-be-written data in the first memory region MR1 from the main processing unit 1, the writing control unit 3 controls the memory cell driving unit 5 to write the to-be-written data in a writing-target memory unit MU1. More specifically, a threshold voltage corresponding to a value of a higher-order bit B 1 of the two bits of to-be-written data is set for the memory cell transistor 16a included in the writing-target memory unit MU1 to thereby write the value of the higher-order bit B1, and a threshold voltage corresponding to a value of a lower-order bit B0 is set for the other memory cell transistor 16b to thereby write the value of the lower-order bit B0.

On the other hand, upon receipt of two bits of to-be-written data in the second memory region MR2 from the main processing unit 1, the writing control unit 3 controls the memory cell driving unit 5 to write the to-be-written data in a writing-target memory unit MU2. More specifically, one of the threshold voltages Vth1 to Vth4 that corresponds to a value of the to-be-written data is set for the memory cell transistor 16 forming the writing-target memory unit MU2 to thereby write the to-be-written data.

When data is read from the first memory region MR1, the reading control unit 4 controls the memory cell driving unit 5 to read one bit of data from each of the memory cell transistors 16a and 16b forming a reading-target memory unit MU1. More specifically, the reading control unit 4 notifies the memory cell driving unit 5 of the reading-target memory unit MU1, and the memory cell driving unit 5 reads data from each of the memory cell transistors 16a and 16b forming the notified memory unit MU1 and outputs the read data to the reading control unit 4.

The reading control unit 4 then combines the one bit of data read from the memory cell transistor 16a as a higher-order bit B1 and the one bit of data read from the memory cell transistor 16b as a lower-order bit B0 to form two bits of data, and outputs the two bits of data as data stored in the reading-target memory unit MU1 to the main processing unit 1.

On the other hand, when data is read from the second memory region MR2, the reading control unit 4 controls the memory cell driving unit 5 to read data from the memory cell transistor 16 forming a reading-target memory unit MU2, and outputs the data directly to the main processing unit 1. More specifically, the reading control unit 4 notifies the memory cell driving unit 5 of the reading-target memory unit MU2, and the memory cell driving unit 5 reads two bits of data from the memory cell transistor 16 forming the notified memory unit MU2 and outputs the read data to the reading control unit 4. The reading control unit 4 then outputs the two bits of data supplied as data stored in the reading-target memory unit MU2 to the main processing unit 1.

In this manner, when data is written in the memory cell transistor 16 in the first memory region MR1 of the memory cell array 6 according to this embodiment, only N types of threshold voltages having values not adjacent to each other are used of the settable M types of threshold voltages Vth1 to VthM for the memory cell transistor 16. This allows the space to be increased between threshold voltages actually set for the memory cell transistor 16. Accordingly, the occurrence of error in read data from the memory cell transistor 16 can be reduced, although the amount of information that can be stored in one memory cell transistor 16 decreases. Therefore, the occurrence of error in read data from the memory unit MU1 can be reduced.

Generally speaking, as the number of data writing in the memory cell transistor 16 increases, the shapes of the distribution mountains of the threshold voltages tend to be altered, which increases the probability of occurrence of error in read data. For this reason, the permissible number of data writing in the memory cell transistor 16 is significantly limited in a multi-level memory having narrow space between threshold voltages. In the first memory region MR1 according to this embodiment, the wide space between the threshold voltages set for the memory cell transistor 16 allows data to be read correctly from the memory cell transistor 16 even with slight shape alterations to the distribution mountains of the threshold voltages resulting from an increase in the number of data writing. The permissible number of data writing in the memory cell transistor 16 can therefore be increased.

Also in this embodiment, only the minimum threshold voltage Vth1 and the maximum threshold voltage Vth4 are used of the four types of threshold voltages Vth1 to Vth4 in writing data in the memory cell transistor 16 in the first memory region MR1. This attains the widest space between threshold voltages set for the memory cell transistor 16. Therefore, the occurrence of error in read data from the memory cell transistor 16 can be reduced more reliably.

Further in this embodiment, the different methods of setting threshold voltages for the memory cell transistors 16 in writing data in the memory cell transistors 16 attain the memory cell transistors 16 in the first memory region MR1 having a relatively low probability of occurrence of data error although the amount of information that can be stored in one memory cell is relatively small, and the memory cell transistors 16 in the second memory region MR2 having a relatively large amount of information that can be stored in one memory cell although the probability of occurrence of data error is relatively high. Thus, the memory cell transistors 16 in the first memory region MR1 and second memory region MR2 can be formed using the same structure. Therefore, a semiconductor storage device having two types of memory cells can be realized using a simple structure, which cuts the manufacturing cost of the semiconductor storage device.

### Second Preferred Embodiment

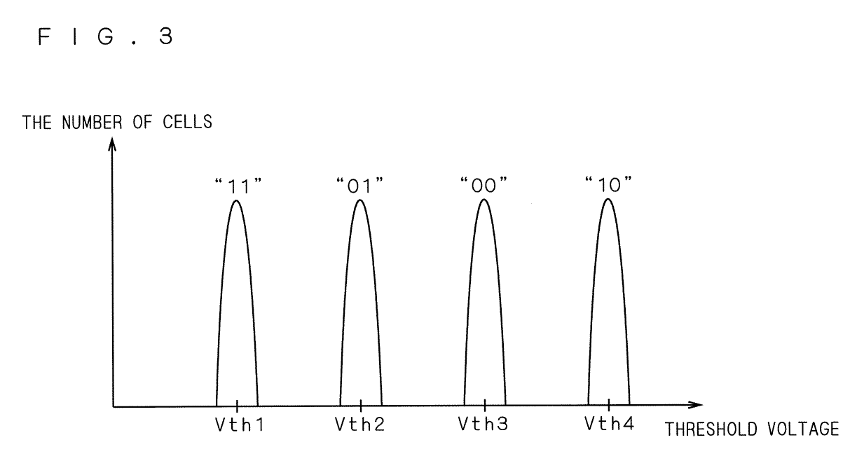

FIG. 4 is a cross-sectional view illustrating the structure of a memory cell transistor 16 included in an information processing device according to a second preferred embodiment of the present invention. The information processing device according to this embodiment is the information processing device according to the above first preferred embodiment that uses the memory cell transistor 16 shown in FIG. 4 for the memory cell array 6. The information processing device according to this embodiment will be described, focusing on differences from the information processing device according to the first preferred embodiment.

The memory cell transistor 16 according to this embodiment is a memory cell transistor physically including two regions for accumulating electric charge, like the one described in the above-mentioned Japanese Patent Application Laid-Open No. 2003-273256. As shown in FIG. 4, the memory cell transistor 16 includes two n-type impurity regions 261 and 262 formed with a prescribed distance therebetween in an upper surface of a p-type semiconductor substrate 260, a first silicon oxide film 263 formed on the upper surface of the semiconductor substrate 260 between the impurity regions 261 and 262, a silicon nitride film 264 formed on the first silicon oxide film 263, a second silicon oxide film 265 formed on the silicon nitride film 264, and a gate electrode 266 formed on the second silicon oxide film 265. The silicon nitride film 264 includes two electric charge accumulation regions 270 and 271.

The memory cell transistor 16 according to this embodiment stores data of a value in accordance with the amount of electric charge accumulated in the electric charge accumulation region 270. Aside from this data, the memory cell transistor 16 stores data of a value in accordance with the amount of electric charge accumulated in the electric charge accumulation region 271.

The amount of electric charge accumulated in the electric charge accumulation region 271 determines a threshold voltage of the memory cell transistor 16 when the impurity regions 261 and 262 serve as a drain region and a source region, respectively. The amount of electric charge accumulated in the electric charge accumulation region 270 determines a threshold voltage of the memory cell transistor 16 when the impurity regions 261 and 262 serve as a source region and a drain region, respectively. Thus the memory cell transistor 16 according to this embodiment stores data of a value in accordance with the threshold voltage when the impurity regions 261 and 262 serve as a drain region and a source region, respectively, and also stores data of a value in accordance with the threshold voltage when the impurity regions 261 and 262 serve as a source region and a drain region, respectively. The case where the impurity regions 261 and 262 serve as a drain region and a source region, respectively, will henceforth be called a “first operation mode”, and the case where the impurity regions 261 and 262 serve as a source region and a drain region, respectively, will be called a “second operation mode”.

For the memory cell transistor 16 according to this embodiment, M types of threshold voltages VAth1 to VAthM in the first operation mode can be set by accumulating electric charge in the electric charge accumulation region 271 by the memory cell driving unit 5 under the control of the writing control unit 3. Also for the memory cell transistor 16 according to this embodiment, M types of threshold voltages VBth1 to VBthM in the second operation mode can be set by accumulating electric charge in the electric charge accumulation region 270 by the memory cell driving unit 5 under the control of the writing control unit 3. The threshold voltages VAth1 to VAthM and the threshold voltages VBth1 to VBthM may be completely the same, or partially or completely different. The threshold voltages VAth1 to VAthM have different values, and the threshold voltages VBth1 to VBthM have different values.

For example, four types of threshold voltages VAth1 to VAth4 (VAth1<VAth2<VAth3<VAth4) as threshold voltages in the first operation mode, and four types of threshold voltages VBth1 to VBth4 (VBth1<VBth2<VBth3<VBth4) as threshold voltages in the second operation mode can be set for the memory cell transistor 16 according to this embodiment. Of the threshold voltages VAth1 to VAth4, only N (≧2) types of threshold voltages having values not adjacent to each other are used in writing data corresponding to a threshold voltage in the first operation mode in the memory cell transistor 16 in the first memory region MR1. Likewise, of the threshold voltages VBth1 to VBth4, only N types of threshold voltages having values not adjacent to each other are used in writing data corresponding to a threshold voltage in the second operation mode. On the other hand, all of the four types of threshold voltages VAth1 to VAth4 are used in writing data corresponding to a threshold voltage in the first operation mode in the memory cell transistor 16 in the second memory region MR2. Likewise, all of the four types of threshold voltages VBth1 to VBth4 are used in writing data corresponding to a threshold voltage in the second operation mode.

In this embodiment, two types of the settable threshold voltages VAth1 to VAth4, i.e. the minimum threshold voltage VAth1 and the maximum threshold voltage VAth4 are used in writing data corresponding to a threshold voltage in the first operation mode in the memory cell transistor 16 in the first memory region MR1, and two types of the settable threshold voltages VBth1 to VBth4, i.e. the minimum threshold voltage VBth1 and the maximum threshold voltage VBth4 are used in writing data corresponding to a threshold voltage in the second operation mode. The two types of threshold voltages VAth1 and VAth4 are used to write one bit of data corresponding to a threshold voltage in the first operation mode in the memory cell transistor 16 in the first memory region MR1, and the two types of threshold voltages VBth1 and VBth4 are used to write one bit of data corresponding to a threshold voltage in the second operation mode. For example, the threshold voltages VAth1 and VBth1 are set for writing data of “0” in the memory cell transistor 16 in the first memory region MR1, and the threshold voltages VAth4 and VBth4 are set for writing data of “1”. As a result, a total of two bits of data, namely, data of four values can be written in one memory cell transistor 16 in the first memory region MR1.

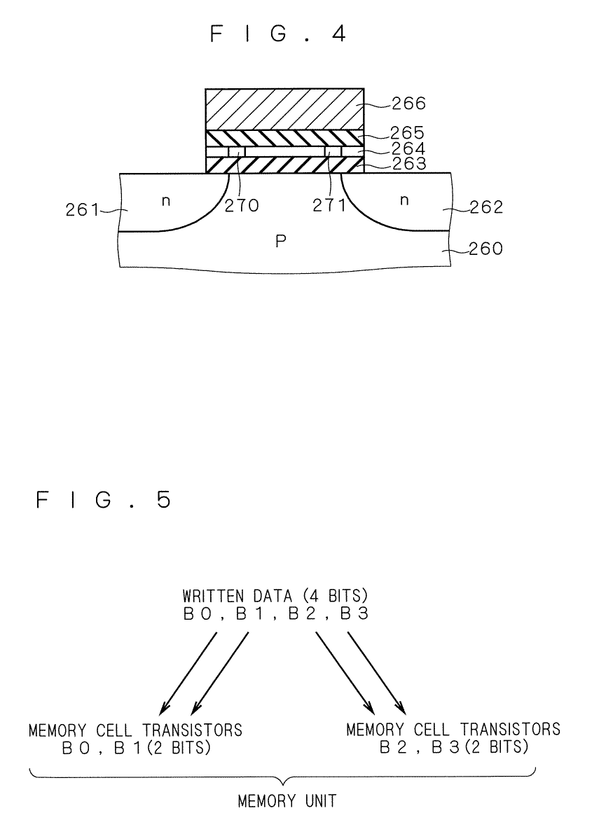

Like the first preferred embodiment, two memory cell transistors 16a and 16b form the memory unit MU1 in the first memory region MR1 of the memory cell array 6 according to this embodiment. The entire memory unit MU1 is capable of storing four bits of data. For example, assuming that bits from the least significant bit to the most significant bit of four bits of data to be written in the memory unit MU1 are bits B0 to B3, respectively, data of the higher-order two bits B2 and B3 are written in the memory cell transistor 16a, and data of the lower-order two bits B0 and B1 are written in the other memory cell transistor 16b, as shown in FIG. 5. When data is read from the memory unit MU1, two bits of data is read from each of the memory cell transistors 16a and 16b forming the memory unit MU 1, to be combined and output as four bits of data.

On the other hand, the threshold voltages VAth1 to VAth4 are used to write two bits of data corresponding to a threshold voltage in the first operation mode in the memory cell transistor 16 in the second memory region MR2, and the threshold voltages VBth1 to VBth4 are used to write two bits of data corresponding to a threshold voltage in the second operation mode. For example, the threshold voltages VAth1 and VBth1 are set for writing data of “11” in the memory cell transistor 16 in the second memory region MR2, and the threshold voltages VAth2 and VBth2 are set for writing data of“01”. The threshold voltages VAth3 and VBth3 are set for writing data of “00” in the memory cell transistor 16, and the threshold voltages VAth4 and VBth4 are set for writing data of “10”. As a result, a total of four bits of data, namely, data of sixteen values can be written in one memory cell transistor 16 in the second memory region MR2. Four bits of data can thus be stored in each memory unit MU2 because, as in the first preferred embodiment, one memory cell transistor 16 forms the memory unit MU2 in the second memory region MR2 of the memory cell array 6 according to this embodiment. The threshold voltages VAth1 to VAthM may henceforth collectively be called a “threshold voltage VAth”, and the threshold voltages VBth1 to VBthM may collectively be called a “threshold voltage VBth”.

Next, the methods of writing data in the first memory region MR1 and second memory region MR2, and the methods of reading data from the first memory region MR1 and second memory region MR2 in the information processing device according to this embodiment will now be described in detail.

Upon receipt of four bits of to-be-written data in the first memory region MR1 from the main processing unit 1, the writing control unit 3 controls the memory cell driving unit 5 to write the to-be-written data in a writing-target memory unit MU1.

For example, assuming that bits from the least significant bit to the most significant bit of the to-be-written data are bits B0 to B3, respectively, a threshold voltage VAth corresponding to a value of the bit B2 is set for the memory cell transistor 16a forming a writing-target memory unit MU1 by accumulating a prescribed amount of electric charge in the electric charge accumulation region 271 of the memory cell transistor 16a, to thereby write data of the bit B2 in the memory cell transistor 16a. Also, a threshold voltage VBth corresponding to a value of the bit B3 is set for the memory cell transistor 16a by accumulating a prescribed amount of electric charge in the electric charge accumulation region 270 of the memory cell transistor 16a, to thereby write data of the bit B3 in the memory cell transistor 16a. Further, a threshold voltage VAth corresponding to a value of the bit B0 is set for the other memory cell transistor 16b forming the writing-target memory unit MU1 by accumulating a prescribed amount of electric charge in the electric charge accumulation region 271 of the memory cell transistor 16b, to thereby write data of the bit B0 in the memory cell transistor 16b. Also, a threshold voltage VBth corresponding to a value of the bit B1 is set for the memory cell transistor 16b by accumulating a prescribed amount of electric charge in the electric charge accumulation region 270 of the memory cell transistor 16b, to thereby write data of the bit B1 in the memory cell transistor 16b.

On the other hand, upon receipt of four bits of to-be-written data in the second memory region MR2 from the main processing unit 1, the writing control unit 3 controls the memory cell driving unit 5 to write the to-be-written data in a writing-target memory unit MU2. For example, threshold voltages VAth corresponding to values of the higher-order two bits B2 and B3 of the four bits of to-be-written data are set for the memory cell transistor 16 forming the writing-target memory unit MU2 by accumulating a prescribed amount of electric charge in the electric charge accumulation region 271 of the memory cell transistor 16, to thereby write data of the two bits B2 and B3 in the memory cell transistor 16. Also, threshold voltages VBth corresponding to values of the lower-order two bits B0 and B1 of the four bits of to-be-written data are set for the memory cell transistor 16 by accumulating a prescribed amount of electric charge in the electric charge accumulation region 270 of the memory cell transistor 16, to thereby write data of the two bits B0 and B1 in the memory cell transistor 16.

When data is read from the first memory region MR1, the reading control unit 4 firstly notifies the memory cell driving unit 5 of a reading-target memory unit MU1. Then, the memory cell driving unit 5 reads one bit of data corresponding to a threshold voltage in the first operation mode and one bit of data corresponding to a threshold voltage in the second operation mode from each of the memory cell transistors 16a and 16b forming the notified memory unit MU1.

The reading control unit 4 then combines the one bit of data corresponding to a threshold voltage in the first operation mode and the one bit of data corresponding to a threshold voltage in the second operation mode read from the memory cell transistor 16a forming the reading-target memory unit MU1, as bits B2 and B3, respectively, and the one bit of data corresponding to a threshold voltage in the first operation mode and the one bit of data corresponding to a threshold voltage in the second operation mode read from the other memory cell transistor 16b forming the reading-target memory unit MU1, as bits B0 and B1, respectively, to form four bits of data. Then, the reading control unit 4 outputs the four bits of data thus formed as data stored in the reading-target memory unit MU1 to the main processing unit 1.

On the other hand, when data is read from the second memory region MR2, the reading control unit 4 firstly notifies the memory cell driving unit 5 of a reading-target memory unit MU2. Then, the memory cell driving unit 5 sets an operation mode of the memory cell transistor 16 forming the notified memory unit MU2 to the first operation mode, to read two bits of data corresponding to a threshold voltage in the first operation mode from the memory cell transistor 16 and output the data to the reading control unit 4. Also, the memory cell driving unit 5 sets an operation mode of the memory cell transistor 16 forming the reading-target memory unit MU2 to the second operation mode, to read two bits of data corresponding to a threshold voltage in the second operation mode from the memory cell transistor 16 and output the data to the reading control unit 4.

The reading control unit 4 then combines the two bits of data corresponding to a threshold voltage in the first operation mode and the two bits of data corresponding to a threshold voltage in the second operation mode read from the memory cell transistor 16 forming the reading-target memory unit MU2, as higher-order two bits B2 and B3 and lower-order two bits B0 and B1, respectively, to form four bits of data. Then, the reading control unit 4 outputs the four bits of data thus formed as data stored in the reading-target memory unit MU2 to the main processing unit 1.

In this manner, when data corresponding to a threshold voltage in the first operation mode is written in the memory cell transistor 16 in the first memory region MR1 of the memory cell array 6 according to this embodiment, only N types of threshold voltages having values not adjacent to each other are used of the settable M types of threshold voltages VAth1 to VAthM for the memory cell transistor 16. When data corresponding to a threshold voltage in the second operation mode is written in the memory cell transistor 16, only N types of threshold voltages having values not adjacent to each other are used of the settable M types of threshold voltages VBth1 to VBthM for the memory cell transistor 16. This allows the space to be increased between threshold voltages in the first and second operation modes actually set for the memory cell transistor 16. Accordingly, the occurrence of error in read data from the memory cell transistor 16 can be reduced, although the amount of information that can be stored in one memory cell transistor 16 decreases. Therefore, the occurrence of error in read data from the memory unit MU1 can be reduced.

Further in the first memory region MR1 according to this embodiment, the wide space between the threshold voltages set for the memory cell transistor 16 allows data to be read correctly from the memory cell transistor 16 even with slight shape alterations to the distribution mountains of the threshold voltages resulting from an increase in the number of data writing. The permissible number of data writing in the memory cell transistor 16 can therefore be increased.

Also in this embodiment, only the minimum threshold voltage VAth1 and the maximum threshold voltage VAth4 are used of the four types of threshold voltages VAth1 to VAth4 in writing data corresponding to a threshold voltage in the first operation mode in the memory cell transistor 16 in the first memory region MR1. This attains the widest space between threshold voltages in the first operation mode set for the memory cell transistor 16. Meanwhile, only the minimum threshold voltage VBth1 and the maximum threshold voltage VBth4 are used of the four types of threshold voltages VBth1 to VBth4 in writing data corresponding to a threshold voltage in the second operation mode in the memory cell transistor 16 in the first memory region MR1. This attains the widest space between threshold voltages in the second operation mode set for the memory cell transistor 16. Therefore, the occurrence of error in read data from the memory cell transistor 16 can be reduced more reliably.

Further in this embodiment, the different methods of setting threshold voltages for the memory cell transistors 16 in writing data in the memory cell transistors 16 attain the memory cell transistors 16 in the first memory region MR1 having a relatively low probability of occurrence of data error although the amount of information that can be stored in one memory cell is relatively small, and the memory cell transistors 16 in the second memory region MR2 having a relatively large amount of information that can be stored in one memory cell although the probability of occurrence of data error is relatively high. Thus, the memory cell transistors 16 in the first memory region MR1 and second memory region MR2 can be formed using the same structure. Therefore, a semiconductor storage device having two types of memory cells can be realized using a simple structure, which cuts the manufacturing cost of the semiconductor storage device.

While the memory cell transistor 16 in the first memory region MR1 stores both of the one bit of data corresponding to a threshold voltage in the first operation mode and the one bit of data corresponding to a threshold voltage in the second operation mode in this embodiment, the memory cell transistor 16 may store only one of the data. In such case, four memory cell transistors 16 form the memory unit MU1 since the memory unit MU1 stores four bits of data. Methods of writing data in and reading data from the memory cell transistor 16 in this case will be described. In the following description, the four memory cell transistors 16 forming the memory unit MU1 will be called memory cell transistors 16a to 16d, respectively. Also, the memory cell transistor 16 in the first memory region MR1 shall store only one bit of data corresponding to a threshold voltage in the first operation mode.

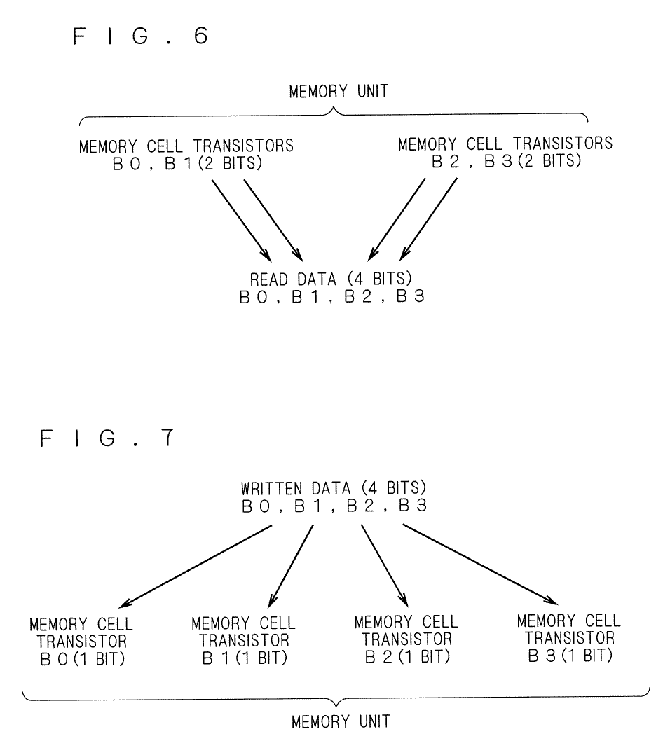

When four bits of data is written in the memory unit MU1 in the first memory region MR1, the four bits of data is divided into one bits, as shown in FIG. 7, and the resultant four one-bit data are written in the four memory cell transistors 16a to 16d forming the memory unit MU1, respectively. For example, a threshold voltage VAth corresponding to a value of the most significant bit B3 of the to-be-written data is set for the memory cell transistor 16a in the writing-target memory unit MU1 to thereby write the value of the bit B3. A threshold voltage VAth corresponding to a value of the second bit B2 from the higher-order level of the to-be-written data is set for the memory cell transistor 16b in the writing-target memory unit MU1 to thereby write the value of the bit B2. A threshold voltage VAth corresponding to a value of the third bit B1 from the higher-order level of the to-be-written data is set for the memory cell transistor 16c in the writing-target memory unit MU1 to thereby write the value of the bit B1. A threshold voltage VAth corresponding to a value of the least significant bit B0 of the to-be-written data is set for the memory cell transistor 16d in the writing-target memory unit MU1 to thereby write the value of the bit B0. One bit of data is thus written in each of the memory cell transistors 16a to 16d forming the memory unit MU1 and, as a result, four bits of data is written in the entire memory unit MU1.

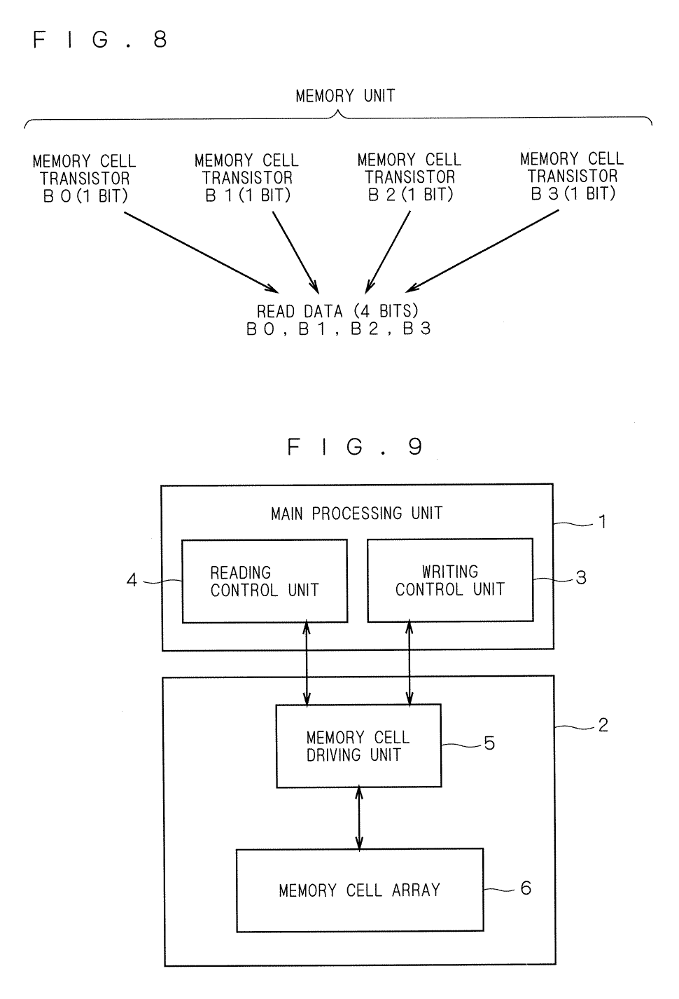

When data is read from the memory unit MU1 in the first memory region MR1, the reading control unit 4 controls the memory cell driving unit 5 to read one bit of data from each of the four memory cell transistors 16a to 16d forming a reading-target memory unit MU1, as shown in FIG. 8. The reading control unit 4 then combines the one bit of data read from the memory cell transistor 16a as a bit B3, the one bit of data read from the memory cell transistor 16b as a bit B2, the one bit of data read from the memory cell transistor 16c as a bit B1, and the one bit of data read from the memory cell transistor 16d as a bit B0, to form four bits of data. Then, the reading control unit 4 outputs the four bits of data thus formed as data stored in the reading-target memory unit MU1 to the main processing unit 1.

In this manner, only data corresponding to a threshold voltage in one of the first and second operation modes is written in the memory cell transistor 16 in the first memory region MR1. Put another way, electric charge is accumulated in only one of the two electric charge accumulation regions 270 and 271 of the memory cell transistor 16 in the first memory region MR1. The result is a further lower probability of occurrence of error in read data from the memory cell transistor 16. The permissible number of data writing in the memory cell transistor 16 can therefore be further increased.

Alternatively, the first memory region MR1 may be divided into two regions so that the memory cell transistor 16 in one of the regions stores both data corresponding to a threshold voltage in the first operation mode and data corresponding to a threshold voltage in the second operation mode, while the memory cell transistor 16 in the other region stores only data corresponding to a threshold voltage in one of the first and second operation modes. In this case, the memory cell array 6 includes three types of memory cell transistors 16, i.e. a memory cell transistor 16 storing one bit of data with an extremely low probability of occurrence of data error, a memory cell transistor 16 storing two bits of data with a relatively low probability of occurrence of data error, and a memory cell transistor 16 storing four bits of data with a relatively high probability of occurrence of data error. That is, the memory cell array 6 includes three types of memory cell transistors 16 having different amounts of information that can be stored and different probabilities of occurrence of data error. Accordingly, the three types of memory cell transistors 16 can be used appropriately depending on the type of to-be-written data while using the same memory cell structure.

While “M” is equal to 4 in the first and second preferred embodiments, the occurrence of error in read data can be reduced in the same way when “M” is equal to 8. Methods of writing data in and reading data from the first memory region MR1 when “M” is equal to 8 will be described, taking the first preferred embodiment as an example. In the following description, each of the memory units MU1 and MU2 shall be capable of storing three bits of data, namely, data of eight values from “000” to “111”, and threshold voltages Vth1 to Vth8 shall be settable for the memory cell transistor 16. The threshold voltages Vth1 to Vth8 increase in value in that order.

When “M” is equal to 8, two of the eight types of threshold voltages Vth1 to Vth8, e.g. the threshold voltages Vth1 and Vth8 are used in writing data in the memory cell transistor 16 in the first memory region MR1. Three memory cell transistors 16 form the memory unit MU1, each of which is written with one bit of data using the two types of threshold voltages Vth1 and Vth8. For example, the threshold voltage Vth1 is set for writing data of “0” in the memory cell transistor 16, and the threshold voltage Vth8 is set for writing data of “1”. As a result, three bits of data is stored in the entire memory unit MU1 including three memory cell transistors 16.

When data is read from the memory unit MU1 in the first memory region MR1, the reading control unit 4 controls the memory cell driving unit 5 to read one bit of data from each of the three memory cell transistors 16 forming a reading-target memory unit MU1, and combines the data to form three bits of data. Then, the reading control unit 4 outputs the three bits of data thus formed as data stored in the reading-target memory unit MU 1 to the main processing unit 1.

The use of the two types of threshold voltages Vth1 and Vth8 of the settable eight types of threshold voltages Vth1 to Vth8 in writing data in the memory cell transistor 16 in the first memory region MR1 as described above can reduce the occurrence of error in read data from the memory unit MU1, although data density decreases.

Further, with respect to the entire region or only the second memory region MR2 of the memory cell array 6 in the first and second preferred embodiments, an ECC (Error Correcting Code) such as an SEC-DED (Single Error Correcting—Double Error Detecting) code may be added to data written in the memory cell transistor 16, to perform error correction on data read from the memory cell transistor 16. In this case, correction probability can be improved by setting the Hamming distance to “1” between adjacent threshold voltages among a plurality of threshold voltages set for the memory cell transistor 16, as shown in FIG. 3.

Since the probability of occurrence of data error is low in the first memory region MR1 of the memory cell array 6 as mentioned above, error correction on data of the first memory region MR1 can be performed only by adding an ECC of not so great correcting capability to the data of the first memory region MR1. Generally speaking, the greater the ECC's correcting capability, the longer the time required to perform error correction, and thus the longer the time until after the corrected data is output. This causes an increase in access speed to a memory region. The use of ECC of not so great correcting capability to perform error correction on data of the first memory region MR1 allows a reduction in access speed to the first memory region MR1.

While the memory cell array 6 according to the first and second preferred embodiments includes the first memory region MR1 and second memory region MR2, the first memory region MR1 may form the entire region of the memory cell array 6 when mainly handling information with which the occurrence of data error needs to be reduced as much as possible.

Moreover, the main processing unit 1 that performs signal processing concerning principal functions of the information processing device may function as the writing control unit 3 and the reading control unit 4 in the first and second preferred embodiments, as shown in FIG. 9. Namely, the main processing unit 1 may control the memory cell driving unit 5 to write data in the memory cell transistor 16, or read data from the memory cell transistor 16. The same effects as described above can again be obtained in this case.

While the invention has been shown and described in detail, the foregoing description is in all aspects illustrative and not restrictive. It is therefore understood that numerous modifications and variations can be devised without departing from the scope of the invention.

What is claimed is:

1. A semiconductor storage device comprising:
a first memory cell transistor storing first data of values in accordance with first plurality types of threshold voltages;
a writing control unit controlling writing of said first data in said first memory cell transistor; and
a memory cell driving unit writing said first data in said first memory cell transistor under control of said writing control unit, wherein
said writing control unit is capable of setting at least three types of threshold voltages having different values for said first memory cell transistor by controlling said memory cell driving unit, and uses only threshold voltages having values not adjacent to each other of said at least three types of threshold voltages as said first plurality types of threshold voltages in writing said first data in said first memory cell transistor.

2. The semiconductor storage device according to claim 1, wherein
said writing control unit uses only a minimum threshold voltage and a maximum threshold voltage of said at least three types of threshold voltages as said first plurality types of threshold voltages in writing said first data in said first memory cell transistor by controlling said memory cell driving unit.

3. The semiconductor storage device according to claim 1, further comprising
a second memory cell transistor storing second data of values in accordance with second plurality types of threshold voltages, wherein
said writing control unit further controls writing of said second data in said second memory cell transistor,
said memory cell driving unit further writes said second data in said second memory cell transistor under control of said writing control unit, and
said writing control unit uses all of said at least three types of threshold voltages as said second plurality types of threshold voltages in writing said second data in said second memory cell transistor by controlling said memory cell driving unit.

4. The semiconductor storage device according to claim 2, further comprising
a second memory cell transistor storing second data of values in accordance with second plurality types of threshold voltages, wherein
said writing control unit further controls writing of said second data in said second memory cell transistor,
said memory cell driving unit further writes said second data in said second memory cell transistor under control of said writing control unit, and
said writing control unit uses all of said at least three types of threshold voltages as said second plurality types of threshold voltages in writing said second data in said second memory cell transistor by controlling said memory cell driving unit.

5. A method of using a semiconductor storage device including a memory cell transistor, said memory cell transistor storing data of values in accordance with a plurality types of threshold voltages and being capable of being set with at least three types of threshold voltages having different values, said method comprising the steps of:
(a) preparing said semiconductor storage device; and
(b) writing said data in said memory cell transistor of said semiconductor storage device, wherein
only threshold voltages having values not adjacent to each other of said at least three types of threshold voltages are used as said plurality types of threshold voltages in said step (b).
